(19) United States
(12) Patent Application Publication
(10) Pub. No.: US 2026/0187790 A1
(43) Pub. Date: Jul. 2, 2026

(54) FLUX APPLICATION STATE INSPECTION DEVICE AND FLUX APPLICATION STATE INSPECTION METHOD

(71) Applicant: CKD Corporation, Aichi (JP)

(72) Inventors: Kensuke Takamura, Aichi (JP); Satoshi Kanbe, Aichi (JP); Shiori Imaizumi, Aichi (JP); Manabu Okuda, Aichi (JP)

(73) Assignee: CKD Corporation, Aichi (JP)

(21) Appl. No.: 19/546,898

(22) Filed: Feb. 23, 2026

Related U.S. Application Data
(63) Continuation of application No. PCT/JP2024/033286, filed on Sep. 18, 2024.

(30) Foreign Application Priority Data
Oct. 27, 2023 (JP) 2023-184940

(51) Int. Cl. G06T 7/00; G01N 21/88; H04N 23/12; H04N 23/56; H04N 23/74

(52) U.S. Cl. CPC G06T 7/001; G01N 21/8806; H04N 23/12; H04N 23/56; H04N 23/74; G06T 2207/10024; G06T 2207/30141

(57) ABSTRACT

A flux application state inspection device that inspects a transparent or translucent flux applied to an electrode of a circuit board, including: a first illuminator that emits first irradiation light that is ultraviolet light or visible light at a first incident angle not less than 0 degree and not greater than 30 degrees; a second illuminator that emits second irradiation light that is visible light having red or green color, at a larger incident angle than the first incident angle; an imaging device that is disposed above the circuit board such that an optical axis of the imaging device is orthogonal to the circuit board, takes a first image of light radiated from the first illuminator and reflected from the circuit board, and takes a second image of light radiated from the second illuminator and reflected from the circuit board.

### BACKGROUND

### Technical Field

The present disclosure relates to an inspection device and an inspection method of performing an inspection for the application state of flux on a circuit board.

### Description of Related Art

A general procedure of mounting an electronic component on a printed circuit board first prints solder paste on electrodes that are placed on the printed circuit board. The procedure then temporarily fixes an electronic component on the printed circuit board with the solder paste printed thereon by taking advantage of the viscosity of the solder paste. After temporary fixation of the electronic component, the printed circuit board is introduced into a reflow furnace to pass through a predetermined reflow process. This achieves soldering of the electronic component.

With a view to downsizing and reducing the occurrence of a mounting failure, a semiconductor package, such as a ball grid array (BGA), having a plurality of bumps in a spherical shape (solder balls) arrayed regularly on a bottom face thereof has been proposed as the electronic component. In the case of mounting such a semiconductor package as the electronic component on the printed circuit board, there is no need to print the solder paste, but there is only a need to place the bumps relative to the electrodes. In the case of mounting such a semiconductor package on the printed circuit board, however, flux is required to be applied to the electrodes, in order to enhance the wettability of solder, before the pumps are placed on the electrodes.

An inappropriate application state of the flux to the electrodes is likely to be defective and cause an insufficient joint strength of the electronic component with the printed circuit board. Accordingly, an inspection is required to be performed in advance for the application state of the flux, before the electronic component is placed on the printed circuit board. A known inspection device used to perform an inspection for the application state of the flux compares an image of the flux taken by an imaging device with pattern-recognized electrodes (a circuit pattern) and performs an inspection for the application state of the flux (as described in, for example, Patent Literature 1).

In the inspection device described in the above Patent Literature 1, the area of the applied flux is set to be wider than the entire area of the electrodes (the entire area of a printed circuit), and furthermore, the flux is opaque. This configuration thus allows an image of the flux to be taken by the imaging device but does not allow an image of the electrodes (an image of the printed circuit) with the flux applied thereon to be taken by the imaging device. An inspection for the application state of the flux accordingly utilizes the patterned-recognized electrodes, instead of the actual electrodes, as the inspection area. In other words, an inspection for the application state of the flux is performed by using a virtually estimated existence region of electrodes. In order to assure the sufficiently high accuracy of inspection, there is a need to set an appropriate inspection area suitable for the position of the actual electrodes.

One proposed technique for setting the appropriate inspection area suitable for the position of the actual electrodes is, for example, a method of using marks provided on a printed circuit board as a reference (as described in, for example, Patent Literature 2).

### PATENT LITERATURE

Patent Literature 1: Japanese Patent No. 2010-271165A
Patent Literature 2: Japanese Patent No. 2005-286309A

In the method of using marks as a reference, however, an extremely high processing accuracy may be required to set an appropriate inspection area in the case of an inspection of a printed circuit board where a plurality of electrodes are provided at extremely small pitches (for example, a printed circuit board with a semiconductor package, such as a BGA, mounted thereon). Such requirement for the extremely high processing accuracy is likely to increase the processing load and thereby decrease the efficiency of inspection.

Simplification of the processing for the purpose of relieving the processing load is, on the other hand, likely to cause a “deviation” between the inspection area and the position of the actual electrodes. As a result, this is likely to fail in providing the sufficiently high accuracy of inspection.

### SUMMARY

By taking into account the circumstances described above, an object of the present disclosure is to provide, for example, a flux application state inspection device that achieves the high accuracy of inspection, while enabling an inspection area to be set by a relatively simple process.

The following describes each of various aspects of the present disclosure. Functions and advantageous effects that are characteristic of each of the aspects are also described as appropriate.

Aspect 1. There is provided a flux application state inspection device that inspects a transparent or translucent flux applied to an electrode of a circuit board. The flux application state inspection device comprises: a first illuminator that irradiates the circuit board with first irradiation light that is ultraviolet light or visible light at a first incident angle that is not less than 0 degree and not greater than 30 degrees, wherein the ultraviolet light has a wavelength of not lower than 320 nm and not higher than 400 nm, and the visible light has a complementary color of a color of a base material portion of the circuit board; a second illuminator that irradiates the circuit board with second irradiation light that is visible light having red color or green color, at a second incident angle that is larger than the first incident angle; an imaging device that is disposed above the circuit board such that an optical axis of the imaging device is orthogonal to the circuit board, takes a first image of light radiated from the first illuminator to the circuit board and reflected from the circuit board, and takes a second image of light radiated from the second illuminator to the circuit board and reflected from the circuit board; and a control device that: based on the first image, specifies an electrode area that indicates an existing area of the electrode in the circuit board, based on the second image, specifies at least one of a flux application area and an electrode exposure area, wherein the flux application area is located in the electrode area, and the flux is applied to the flux application area, and the electrode exposure area is located in the electrode area, and the electrode is exposed on the electrode exposure area, and detects whether an application state of the flux to the electrode is defective or non-defective, based on at least one of the flux application area and the electrode exposure area that have been specified.

In the flux application state inspection device of above Aspect 1, the first illuminator irradiates the circuit board with the ultraviolet light having the wavelength of not lower than 320 nm and not higher than 400 nm or with the visible light having the complementary color of the color of the base material portion of the circuit board, at the first incident angle of not less than 0 degree and not greater than 30 degrees. In the device of this aspect, the circuit board is irradiated with the light from the first illuminator at a relatively small incident angle, so that the light is regularly reflected by the electrode, irrespective of whether the flux is applied to the electrode, and the light regularly reflected by the electrode is more likely to reach the imaging device. The other part (i.e., the base material portion of the circuit board), on the other hand, absorbs the irradiation light. In the first image obtained by an imaging operation of the imaging device in the state that the circuit board is irradiated with the light from the first illuminator, the electrode is shown as a bright portion, whereas the other part is shown as a dark portion. This configuration accordingly enables the control device to more accurately and more readily specify the electrode area that indicates an existing area of the electrode in the circuit board, or in other words, an inspection area as an object of the detection of whether the flux is appropriate applied, based on the first image. This reduces the processing load in relation to setting of the inspection area and thereby improves the efficiency of the inspection. Furthermore, this configuration enables the inspection area (the electrode area) to be specified without using any mark provided as a reference in the circuit board. This more effectively prevents a decrease in the accuracy of the inspection accompanied with a position change of the reference caused by a change in the shape of the circuit board (for example, a warpage, a contraction or an expansion of the circuit board).

The second illuminator, on the other hand, irradiates the circuit board with the visible light having red color or green color, at the second incident angle that is larger than the first incident angle. In the device of this aspect, the circuit board is irradiated with the light from the second illuminator at a relatively large incident angle, so that the light regularly reflected by an electrode with no flux applied thereto (i.e., an exposed electrode) is unlikely to reach the imaging device. The irregular reflection of the light is, on the other hand, caused by the flux at the electrode with the flux applied thereto, so that the light reflected from this electrode is more likely to reach the imaging device. In the second image obtained by an imaging operation of the imaging device in the state that the circuit board is irradiated with the light from the second illuminator, the exposed electrode is shown as a dark portion, whereas the electrode with the flux applied thereto is shown as a brighter portion than the exposed electrode (for example, a gray portion). This configuration accordingly enables the control device to more accurately and more readily specify the flux application area (the gray portion in the second image) and the electrode exposure area (the dark portion in the second image), based on the second image.

The control device then performs the defective/non-defective detection with regard to the application state of the flux to the electrode, based on at least one of the flux application area and the electrode exposure area that have been specified. As described above, the configuration of this aspect enables the electrode area corresponding to an inspection area to be specified accurately and also enables the flux application area and the electrode exposure area located in this electrode area to be specified accurately. This provides the high accuracy of inspection in the defective/non-defective detection by the control device. This configuration accordingly ensures the sufficient accuracy of inspection even in the case of an inspection with regard to a circuit board provided with a plurality of electrodes arrayed at extremely small pitches (for example, a circuit board with a BGA mounted thereon).

In terms of improving the accuracy of inspection, it is preferable to provide a larger difference between the first incident angle and the second incident angle. More specifically, it is more preferable to provide the difference between the two incident angles to be not less than 30 degrees. It is furthermore preferable to provide the difference between the two incident angles to be not less than 45 degrees.

Aspect 2. In the flux application state inspection device described in above Aspect 1, a wavelength of the first irradiation light and a wavelength of the second irradiation light may be set to be different from each other, and the imaging device may simultaneously take the first image and the second image.

The configuration of above Aspect 2 enables the first image and the second image to be obtained by one imaging operation of the imaging device. This configuration accordingly further enhances the efficiency of the inspection.

Aspect 3. In the flux application state inspection device described in above Aspect 1, the first incident angle may be set to be not less than 0 degree and not greater than 20 degrees.

The configuration of above Aspect 3 makes the light regularly reflected by the electrode more likely to reach the imaging device. This configuration provides a more distinct difference between a luminance value of the electrode and a luminance value of the other part in the first image. This accordingly enables the electrode area (inspection area) to be more accurately specified in the first image and thereby further enhances the accuracy of inspection.

In terms of further enhancing the accuracy of inspection, it is more preferable to set the first incident angle to be not less than 0 degree and not greater than 15 degrees. It is furthermore preferable to set the first incident angle to be not less than 0 degree and not greater than 10 degrees.

Aspect 4. In the flux application state inspection device described in above Aspect 1, the second incident angle may be set to be not less than 55 degrees and not greater than 75 degrees.

The configuration of above Aspect 4 makes the light regularly reflected by the electrode more unlikely to reach the imaging device. This configuration accordingly provides a more distinct difference between a luminance value of an exposed electrode and a luminance value of an electrode with the flux applied thereto, in the second image. As a result, this enables the electrode exposure area and the flux application area to be more accurately specified in the second image and thereby further enhances the accuracy of inspection.

In terms of further enhancing the accuracy of inspection, it is more preferable to set the second incident angle to be not less than 60 degrees and not greater than 70 degrees.

Aspect 5. In the flux application state inspection device described in above Aspect 1, the first illuminator may radiate ultraviolet light having a wavelength of not lower than 320 nm and not higher than 400 nm.

In the flux application state inspection device of above Aspect 5, the first illuminator does not radiate the visible light according to the color of the base material portion of the circuit board but radiates the ultraviolet light. This configuration accordingly does not require to set the irradiation light according to the color of the base material portion of the circuit board in the process of obtaining the first image. This enhances the convenience in relation to the inspection.

Aspect 6. In the flux application state inspection device described in above Aspect 1, the first illuminator may radiate, as the first irradiation light, the visible light having the complementary color of the color of the base material portion of the circuit board. The flux application state inspection device of this aspect may further comprise an input device that receives an input of the color of the base material portion. The control device automatically controls wavelengths of the first irradiation light and the second irradiation light based on the color input via the input device. In a case where the color input via the input device is green color, the control device may set the wavelength of the first irradiation light to be not lower than 625 nm and not higher than 635 nm, or to be not lower than 445 nm and not higher than 455 nm, and set the wavelength of the second irradiation light to be not lower than 520 nm and not higher than 635 nm. In a case where the color input via the input device is blue color, the control device may set the wavelength of the first irradiation light to be not lower than 520 nm and not higher than 635 nm, and set the wavelength of the second irradiation light to be not lower than 520 nm and not higher than 635 nm. In a case where the color input via the input device is red color or brown color, the control device may set the wavelength of the first irradiation light to be not lower than 445 nm and not higher than 530 nm, and set the wavelength of the second irradiation light to be not lower than 520 nm and not higher than 635 nm.

In the flux application state inspection device of above Aspect 6, the color (information with regard to the color) of the base material portion of the circuit board is input by the input device. The configuration of Aspect 6 accordingly enables the wavelengths of the lights respectively radiated from both the illuminators to be automatically set to appropriate wavelengths according to the color of the base material portion. This configuration more certainly assures the high accuracy of inspection and further enhances the convenience in relation to the inspection.

Aspect 7. There is provided a flux application state inspection method for inspecting a transparent or translucent flux applied to an electrode of a circuit board. The flux application state inspection method comprises: a first irradiation process of irradiating the circuit board with first irradiation light that is ultraviolet light or visible light at a first incident angle that is not less than 0 degree and not greater than 30 degrees, wherein the ultraviolet light has a wavelength of not lower than 320 nm and not higher than 400 nm, and the visible light has a complementary color of a color of a base material portion of the circuit board; a second irradiation process of irradiating the circuit board with second irradiation light that is visible light having red color or green color, at a second incident angle that is larger than the first incident angle; a first imaging process of taking, with an imaging device disposed above the circuit board such that an optical axis of the imaging device is orthogonal to the circuit board, a first image of light radiated to the circuit board in the first irradiation process and reflected from the circuit board; a second imaging process of taking, with the imaging device, a second image of light radiated to the circuit board in the second irradiation process and reflected from the circuit board; a first specification process of specifying, based on the first image, an electrode area that indicates an existing area of the electrode in the circuit board; a second specification process of specifying, based on the second image, at least one of a flux application area and an electrode exposure area, wherein the flux application area is located in the electrode area, and the flux is applied to the flux application area, and the electrode exposure area is located in the electrode area, and the electrode is exposed on the electrode exposure area; and a detection process of detecting whether an application state of the flux to the electrode is defective or non-defective, based on at least one of the flux application area and the electrode exposure area that have been specified.

The configuration of above Aspect 7 has similar functions and advantageous effects to those of Aspect 1 described above.

The technical features described above in the respective aspects may be combined appropriately. For example, the technical features with regard to above Aspect 4 may be combined with the technical features with regard to above Aspect 3. In another example, at least one of the technical features with regard to above Aspects 2 to 6 may be applied to above Aspect 7.

### BRIEF DESCRIPTION OF DRAWINGS

FIG. 1 is a schematic plan view illustrating a printed circuit board;

FIG. 2 is a schematic plan view illustrating the printed circuit board with omission of electronic components and the like to show electrodes;

FIG. 3 is a schematic sectional view illustrating partial closeup of the printed circuit board;

FIG. 4 is a schematic perspective view illustrating an electronic component;

FIG. 5 is a sectional view illustrating partial closeup of the electronic component and the like before being mounted on electrodes;

FIG. 6 is a block diagram showing the configuration of a production line of the printed circuit board;

FIG. 7 is a schematic plan view illustrating partial closeup of the printed circuit board to show flux applied on the electrodes;

FIG. 8 is a schematic configuration diagram schematically illustrating a flux application state inspection device;

FIG. 9 is a block diagram showing the functional configuration of the flux application state inspection device;

FIG. 10 is a schematic diagram illustrating a first image;

FIG. 11 is a schematic plan view illustrating partial closeup of the printed circuit board in the case where all of a plurality of electrodes configuring one electrode group are appropriately covered with flux;

FIG. 12 is a schematic diagram illustrating a second image in the case where all of a plurality of electrodes configuring one electrode group are appropriately covered with flux;

FIG. 13 is a schematic plan view illustrating partial closeup of the printed circuit board in the case where part of the plurality of electrodes are not appropriately covered with flux but are exposed; and

FIG. 14 is a schematic diagram illustrating a second image in the case where part of the plurality of electrodes are not appropriately covered with flux but are exposed.

### Detailed Description of Embodiments

The following describes embodiments with reference to drawings. The configuration of a printed circuit board as the “circuit board” is described first.

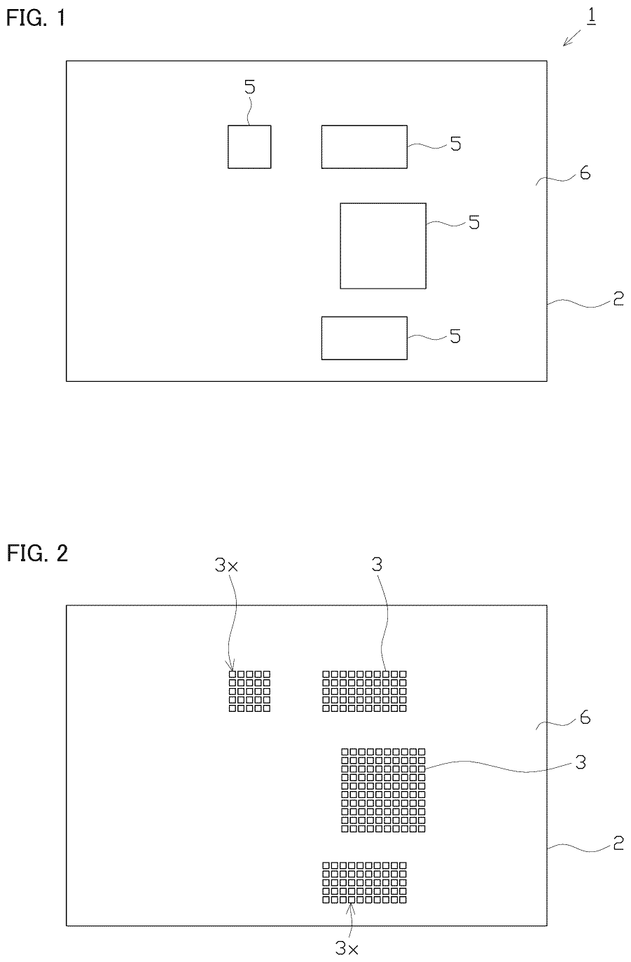

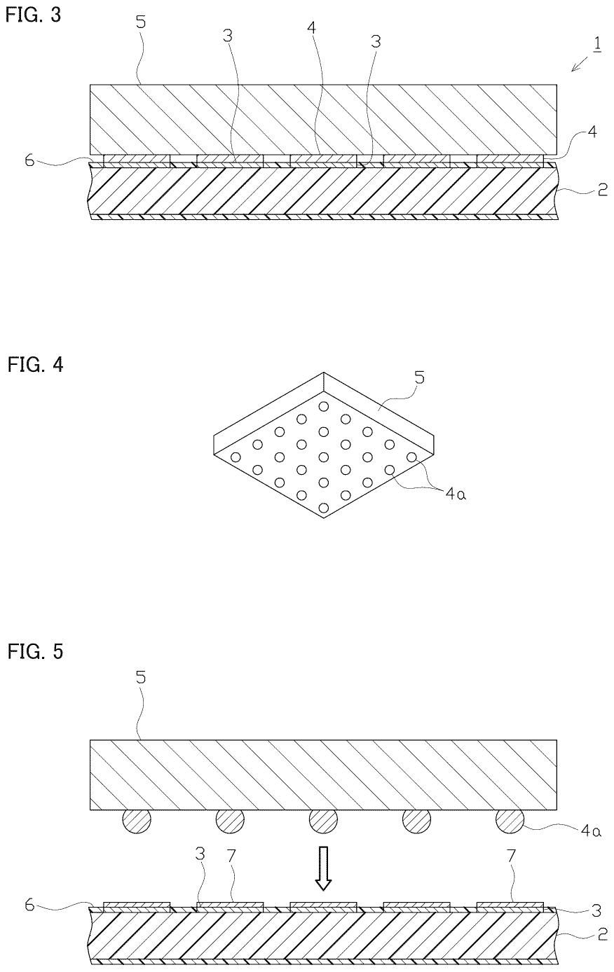

As shown in FIG. 1 to FIG. 3, a printed circuit board 1 (hereinafter simply referred to as the “circuit board 1”) is a glass epoxy circuit board where electrodes 3 (not shown in FIG. 1) made of copper foil and the like are formed on a flat plate-like base substrate 2 made of, for example, a glass epoxy resin. An electronic component 5, such as a chip, is mounted on the electrodes 3 via solder paste 4 that is provided by kneading solder grains with flux (hereinafter simply referred to as “solder 4”).

A region of the base substrate 2 other than the electrodes 3 and a circuit pattern (electrode pattern) is a base material portion 6 comprised of, for example, a glass epoxy resin and a resist, and gives green color according to one or more embodiments.

Furthermore, as shown in FIG. 4, the electronic component 5 according to one or more embodiments is a ball grid array (BGA) where a plurality of bumps 4a are arrayed regularly on a bottom face of the electronic component 5. The respective bumps 4a are fused to be spread over the surface of the electrodes 3 in a reflow process performed by a reflow device 14 described later and eventually forms the solder 4. The base substrate 2 has an electrode group 3x (shown in FIG. 2) consisting of a plurality of electrodes 3 as objects which the respective bumps 4a are placed on for mounting one electronic component 5. In a process of mounting an electronic component 5 on the base substrate 2, each bump 4a is placed on each of the electrodes 3 configuring the electrode group 3x. According to one or more embodiments, the base substrate 2 has a plurality of (for example, four) electrode groups 3x, and one electronic component 5 is mounted on each electrode group 3x. According to one or more embodiments, the pitch of the plurality of electrodes 3 configuring one electrode group 3x is very small (for example, as small as 1.8 mm or less or 0.5 mm or less).

Moreover, as shown in FIG. 5, before the electronic component 5 is mounted on the electrode group 3x, flux 7 is applied in advance on the surface of the plurality of electrodes 3 configuring the electrode group 3x. The flux 7 is used to remove metal oxide films in the electrodes 3, the electronic component 5, and the solder 4 and enhance the wettability of the solder 4. The flux 7 is configured to be transparent or translucent and hardly visible. Furthermore, the flux 7 is configured to individually cover the plurality of electrodes 3 configuring one electrode group 3x.

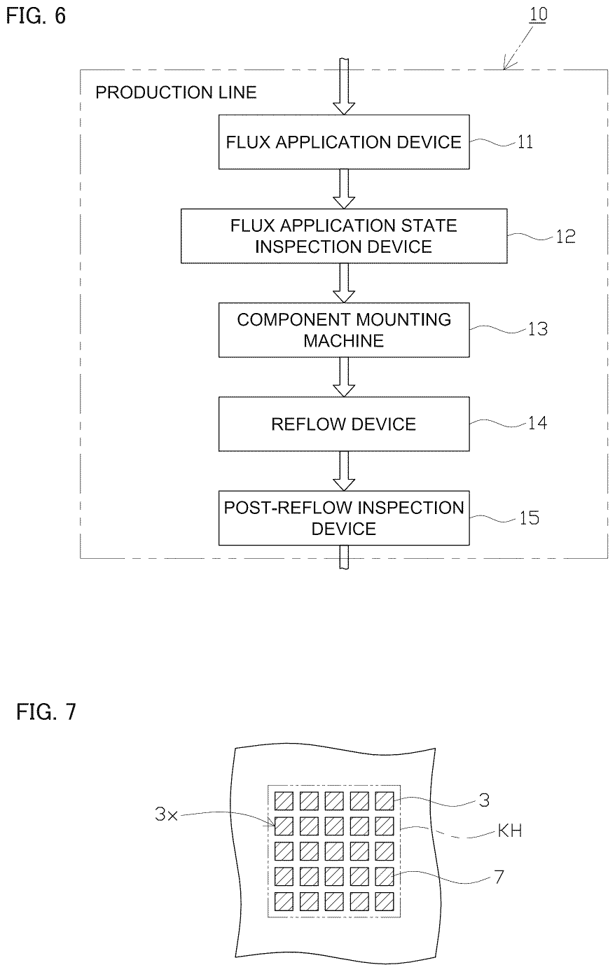

The following describes a production line (manufacturing process) of manufacturing the circuit board 1. As shown in FIG. 6, in a production line 10, a flux application device 11, a flux application state inspection device 12, a component mounting machine 13, a reflow device 14 and a post-reflow inspection device 15 are placed sequentially from an upstream side thereof (from an upper side of FIG. 6). The circuit board 1 is set to be transferred to these devices in this sequence.

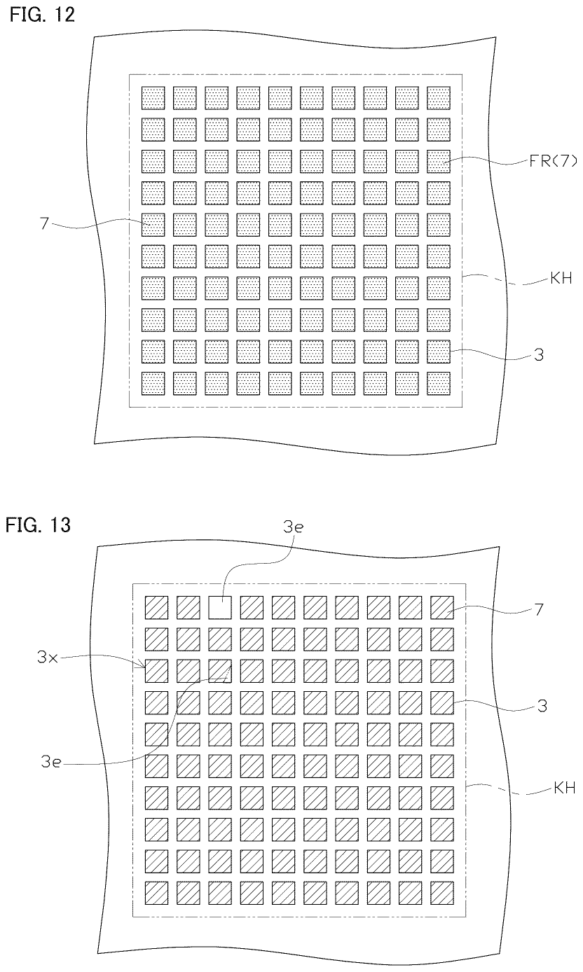

The flux application device 11 is configured to apply the flux 7 on at least the surface of the electrodes 3 of the circuit board 1. For example, the flux application device 11 places a predetermined mask on the circuit board 1 and then applies the flux 7 on the surface of the electrodes 3 by utilizing screen printing. According to one or more embodiments, as shown in FIG. 7, the flux application device 11 applies the flux 7 such as to individually cover the plurality of electrodes 3 configuring one electrode group 3x. FIG. 7, FIG. 11, and FIG. 13 are schematic plan views illustrating partial closeup of the circuit board 1. In these drawings, the flux 7 is shown by slant lines for convenience of illustration. The flux 7 is, however, transparent or translucent. In the actual state, there is accordingly a difficulty in clearly specifying an application area of the flux 7 by visual observation. According to a modification, the flux application device 11 may be configured to apply the flux 7 by using a predetermined dispenser.

The flux application state inspection device 12 is configured to perform an inspection for the application state of the flux 7 that is applied on the electrodes 3. The flux application state inspection device 12 will be described later.

The component mounting machine 13 is configured to perform a component mounting process (mounting process) that mounts the electronic component 5 on the electrodes 3 and the like. The electronic component 5 is accordingly mounted on the electrode group 3x via the bumps 4a.

The reflow device 14 is configured to perform a reflow process that heats and fuses the bumps 4a and the like. In the circuit board 1 subjected to the reflow process, the bumps 4a are fused to be spread over the surface of the electrodes 3 and are eventually solidified to form the solder 4. The solder 4 works to join the electronic component 5 with the electrodes 3.

The post-reflow inspection device 15 is configured to perform a post-reflow inspection process that performs an inspection to determine whether the solder joint is appropriately provided or not in the reflow process. For example, the post-reflow inspection device 15 uses image data or the like of the circuit board 1 after the reflow process to check the presence or the absence of any positional misalignment in the electronic component 5.

The production line 10 is further provided with conveyors or the like between the respective devices described above, for example, between the flux application device 11 and the flux application state inspection device 12, to transfer the circuit board 1, although the illustration is omitted. Furthermore, a branching device is provided between the flux application state inspection device 12 and the component mounting machine 13 and on a downstream side of the post-reflow inspection device 15. The circuit board 1 determined as non-defective by the flux application state inspection device 12 and by the post-reflow inspection device 15 is guided directly to the downstream side. The circuit board 1 determined as defective by at least one of the inspection devices 12 and 15 is, on the other hand, discharged by the branching device to a defective storage (not shown).

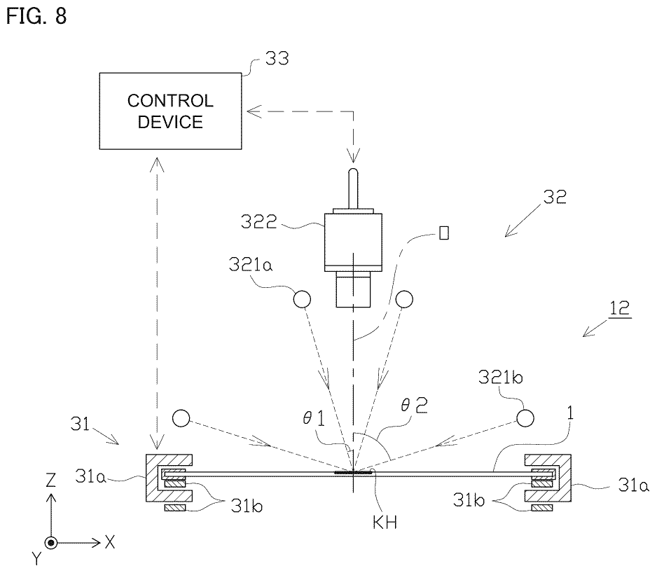

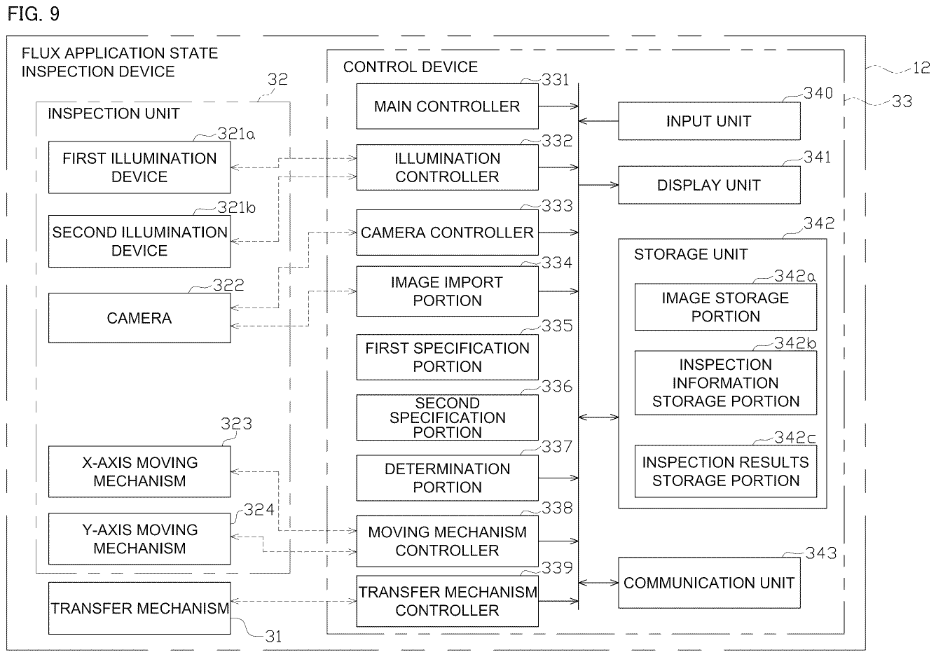

The following describes the configuration of the flux application state inspection device 12. As shown in FIG. 8 and FIG. 9, the flux application state inspection device 12 includes a transfer mechanism 31 configured to, for example, transfer the circuit board 1 and position the circuit board 1; an inspection unit 32 configured to perform an inspection of the flux 7; and a control device 33 configured to drive and control the transfer mechanism 31 and the inspection unit 32 and to perform a variety of controls, image processing, and arithmetic processing in the inspection device 12.

The transfer mechanism 31 includes one pair of transfer rails 31a placed along a carrying in/out direction of the circuit board 1; and an endless conveyor belt 31b placed to be rotatable relative to each of the transfer rails 31a. The transfer mechanism 31 is also provided with a driving unit, such as a motor, configured to drive the conveyor belt 31b and with a chuck mechanism configured to position the circuit board 1 at a predetermined position, although the illustration is omitted. The transfer mechanism 31 is driven and controlled by the control device 33 (more specifically, a transfer mechanism controller 338 thereof described later).

Under the configuration described above, the circuit board 1 carried into the flux application state inspection device 12 is placed on the conveyor belt 31b in the state that respective edges of the circuit board 1 in a width direction perpendicular to the carrying in/out direction are respectively inserted into the transfer rails 31a. The conveyor belt 31b subsequently starts operation, so as to transfer the circuit board 1 to a predetermined inspection position. When the circuit board 1 reaches the inspection position, the conveyor belt 31b stops, and the chuck mechanism described above starts operation. This operation of the chuck mechanism presses up the conveyor belt 31b and causes the respective edges of the circuit board 1 to be sandwiched between the conveyor belt 31b and upper sides of the transfer rails 31a. This positions and fixes the circuit board 1 at the inspection position. On completion of the inspection, the fixation by the chuck mechanism is released, and the conveyor belt 31b starts operation. The circuit board 1 is accordingly carried out from the flux application state inspection device 12. The configuration of the transfer mechanism 31 is, however, not limited to the configuration of the above embodiments, but another configuration may be employed.

The inspection unit 32 is placed above the transfer rails 31a (transfer path of the circuit board 1). The inspection unit 32 is provided with a first illumination device (or first illuminator) 321a, a second illumination device (or second illuminator) 321b, and a camera 322. According to one or more embodiments, the first illumination device 321a configures the “first irradiation unit”, the second illumination device 321b configures the “second irradiation unit”, and the camera 322 configures the “imaging unit” or “imaging device”.

The inspection unit 32 is also provided with an X-axis moving mechanism 323 configured to allow for a movement in an X-axis direction (a left-right direction of FIG. 8) and a Y-axis moving mechanism 324 configured to allow for a movement in a Y-axis direction (a front-back direction of FIG. 8). Both the moving mechanisms 323 and 324 may comprise rails and/or motors, and are driven and controlled by the control device 33 (more specifically, a moving mechanism controller 338 thereof described later).

The first illumination device 321a is configured to irradiate the circuit board 1, which is an object of inspection performed by the flux application state inspection device 12, with visible light having a complementary color of the color of the base material portion 6 of the circuit board 1. According to one or more embodiments, the base material portion 6 has green color. The first illumination device 321a accordingly radiates red visible light (for example, light having a wavelength of not lower than 625 nm and not higher than 635 nm).

Furthermore, the first illumination device 321a irradiates the circuit board 1 with the light radiated from vertically above or from obliquely above. An incident angle θ1 of the light radiated from the first illumination device 321a toward the circuit board 1 (more specifically, toward an inspection target range KH described later) is set to be not less than 0 degree and not greater than 30 degrees. According to one or more embodiments, the incident angle θ1 is especially set to be not less than 0 degree and not greater than 20 degrees. In terms of enhancing the accuracy of inspection, the incident angle θ1 is more preferably not less than 0 degree and not greater than 15 degrees, and is furthermore preferably not less than 0 degree and not greater than 10 degrees. According to one or more embodiments, a process of radiating the light from the first illumination device 321a toward the circuit board 1 corresponds to the “first irradiation process”.

The second illumination device 321b is configured to irradiate the circuit board 1 as the object of inspection with red visible light (for example, light having a wavelength of not lower than 625 nm and not higher than 635 nm) or with green visible light (for example, light having a wavelength of not lower than 520 nm and not higher than 530 nm). The second illumination device 321b irradiates the circuit board 1 with the light at an incident angle θ2, which is larger than the incident angle θ1 of the light which the first illumination device 321a irradiates the circuit board 1 with. According to one or more embodiments, the incident angle θ2 of the light radiated from the second illumination device 321b toward the circuit board 1 (more specifically, toward the inspection target range KH described later) is set to be not less than 55 degrees and not greater than 75 degrees. In terms of enhancing the accuracy of inspection, the incident angle θ2 is more preferably not less than 60 degrees and not greater than 75 degrees, and is furthermore preferably not less than 60 degrees and not greater than 70 degrees. According to one or more embodiments, a process of radiating the light from the second illumination device 321b toward the circuit board 1 corresponds to the “second irradiation process”.

The camera 322 is placed immediately above the circuit board 1 as the object of inspection, such that an optical axis O of the camera 322 is orthogonal to the circuit board 1, and is configured to take an image of an inspection target range KH of the circuit board 1 from immediately above. According to one or more embodiments, the inspection target range KH is set in advance for each of the electronic components 5 that are to be mounted and is specified as a range including all the plurality of electrodes 3 constituting one electrode group 3x (as shown in FIG. 7).

The camera 322 is configured by, for example, a CCD camera having sensitivities to the respective lights radiated from the first illumination device 321a and from the second illumination device 321b and is operated and controlled by the control device 33 (more specifically, a camera controller 333 thereof described later).

The operation control of the control device 33 causes the camera 322 to take an image of the light reflected from the circuit board 1 in the inspection target range KH in the state that the circuit board 1 is irradiated with the light from the first illumination device 321a. A first image with regard to the inspection target range KH is accordingly obtained. The first image is a luminance image and includes a large number of pixels respectively having data with regard to the luminance. According to one or more embodiments, a process of causing the camera 322 to take an image of the light radiated from the first illumination device 321a and reflected from the circuit board 1 corresponds to the “first imaging process”.

Furthermore, the operation control of the control device 33 causes the camera 322 to take an image of the light reflected from the circuit board 1 in the inspection target range KH in the state that the circuit board 1 is irradiated with the light from the second illumination device 321b. A second image with regard to the inspection target range KH is accordingly obtained. Like the first image, the second image is a luminance image and includes a large number of pixels respectively having data with regard to the luminance. According to one or more embodiments, a process of causing the camera 322 to take an image of the light radiated from the second illumination device 321b and reflected from the circuit board 1 corresponds to the “second imaging process”.

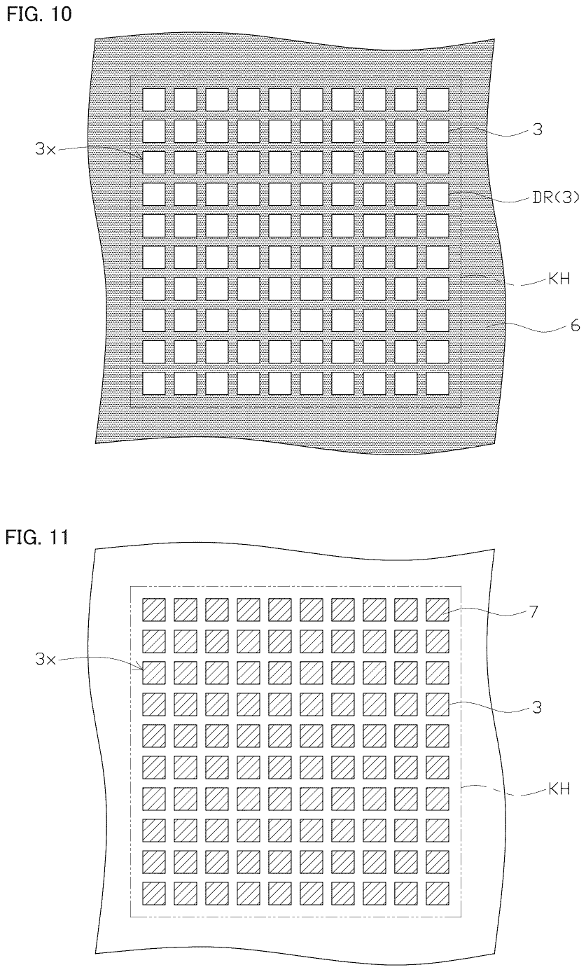

In the first image, the electrode 3 is shown as a bright portion, irrespective of whether the flux 7 is applied to the electrode 3, whereas the other part (the base material portion 6) is shown as a dark portion (for example, as shown in FIG. 10). This is due to the following reasons. The first illumination device 321a radiates the light toward the circuit board 1 at the relatively small incident angle θ1, so that the light is regularly reflected by the electrode 3 and the light regularly reflected from the electrode 3 is more likely to reach the camera 322. The first illumination device 321a, on the other hand, radiates the visible light having the complementary color of the color of the base material portion 6, so that the radiated light is absorbed in the other part (in the base material portion 6).

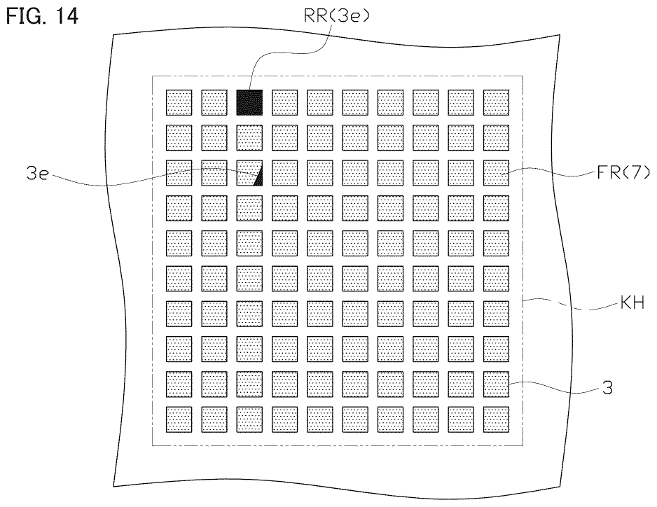

In the second image, the electrode 3 with no flux 7 applied thereto (i.e., an exposed electrode) is shown as a dark portion, whereas the electrode 3 with the flux 7 applied thereto is shown as a brighter gray portion (having a higher luminance value) than the exposed electrode. This is due to the following reasons. The second illumination device 321b radiates the light toward the circuit board 1 at the relatively large incident angle θ2, so that the light regularly reflected from the exposed electrode is unlikely to reach the camera 322. The irregular reflection of the light is, on the other hand, caused by the flux 7 at the electrode 3 with the flux 7 applied thereto, so that the light reflected from this electrode 3 is more likely to reach the camera 322. Accordingly, in the case where all of the plurality of electrodes 3 configuring one electrode group 3x are appropriately covered with the flux 7 (for example, as shown in FIG. 11), all the electrodes 3 are shown as gray portions in the second image (for example, as shown in FIG. 12). In the case where part or the entirety of the electrodes 3 are not appropriately covered with the flux 7 but there is any exposed electrode 3e that is the electrode 3 exposed thereon (for example, as shown in FIG. 13), on the other hand, the exposed electrode 3e is shown as a dark portion that is darker than (having a lower luminance value than) the above gray portion in the second image (for example, as shown in FIG. 14).

The first image and the second image obtained by the camera 322 are transferred to the control device 33 (an image import portion 334 thereof described later). The control device 33 performs an inspection process for the application state of the flux 7, based on these images.

The control device 33 is configured by a computer including a CPU (Central Processing Unit) which executes predetermined arithmetic operations, a ROM (Read Only Memory) which stores a variety of programs, fixed value data and the like, a RAM (Random Access Memory) where a variety of data are temporarily stored in the course of execution of various arithmetic operations, and peripheral circuits thereof.

The CPU operates according to the various programs, so that the control device 33 serves as various functional portions, such as a main controller 331, an illumination controller 332, a camera controller 333, an image import portion 334, a first specification portion 335, a second specification portion 336, a determination portion 337, a moving mechanism controller 338, and a transfer mechanism controller 339.

The respective functional portions described above are implemented by cooperation of various hardware components, such as the CPU, the ROM and the RAM, described above. There is no need to clearly distinguish the functions implemented by the hardware configuration from the functions implemented by the software configuration. Part or the entirety of these functions may be implemented by a hardware circuit, such as an IC. According to one or more embodiments, the first specification portion 335 configures the “first specification unit”; the second specification portion 336 configures the “second specification unit”; and the determination portion 337 configures the “determination unit”.

The control device 33 is further provided with, for example, an input unit (or input device) 340 that is configured by a keyboard and a mouse, a touch panel or the like; a display unit (or display device) 341 that is configured by a liquid crystal display or the like and that is provided with a display screen; a storage unit (or storage) 342 that is configured to store a variety of data, programs, results of arithmetic operations, results of inspections and the like; and a communication unit 343 that is configured to send and receive various data to and from outside. The storage unit 342 and the communication unit 343 are described first. According to one or more embodiments, the input unit 340 configures the “input unit”.

The storage unit 342 is configured by a memory device, such as an HDD (Hard Disk Drive) or an SSD (Solid State Drive) to store various pieces of information. The storage unit 342 includes an image storage portion 342a, an inspection information storage portion 342b, and an inspection results storage portion 342c.

The image storage portion 342a is configured to store the images taken and obtained by the camera 322. The images stored in the image storage portion 342a can be appropriately displayed on the display unit 341.

The inspection information storage portion 342b is configured to store various pieces of information that are used for the inspection of the flux 7. The inspection information storage portion 342b stores therein, for example, a variety of threshold values and numerical ranges that are used for binarization of the images and for defective/non-defective determination, design data, production data and the like. The design data and the production data include, for example, planned application areas of the flux 7 and mounting areas of the electronic components 5. The inspection target range KH described above is set, based on the design data and the production data.

The inspection results storage portion 342c is configured to store inspection results data of an inspection with regard to the application state of the flux 7 performed by the determination portion 337. The inspection results storage portion 342c also stores therein, for example, statistical data obtained by stochastic and statistic processing of the inspection results data. These inspection results data and statistical data can be appropriately displayed on the display unit 341.

The communication unit 343 is provided with, for example, a communication interface in conformity with a communications standard, such as a wired LAN (Local Area Network) and a wireless LAN and is configured to send and receive various data to and from the outside. For example, results of an inspection performed by the determination portion 337 are output to the outside via the communication unit 343. Results of an inspection performed by the post-reflow inspection device 15 are input via the communication unit 343.

The following describes the details of the above respective functional portions of the control device 33. More specifically, the following first describes the moving mechanism controller 338 and the transfer mechanism controller 339 and then describes the main controller 331 and the other functional portions.

The moving mechanism controller 338 is a functional portion of driving and controlling the X-axis moving mechanism 323 and the Y-axis moving mechanism 324 and is configured to control the position of the inspection unit 32, based on a command signal from the main controller 331. The moving mechanism controller 338 drives and controls the X-axis moving mechanism 323 and the Y-axis moving mechanism 324, such as to move the inspection unit 32 to a position above an arbitrary inspection target range KH in the circuit board 1 that is positioned and fixed at the inspection position. The inspection unit 32 is sequentially moved to a plurality of inspection target ranges KH set in the circuit board 1 and sequentially performs inspections with regard to the plurality of inspection target ranges KH. This implements an inspection for the flux 7 in all the inspection target ranges KH.

The transfer mechanism controller 339 is a functional portion of driving and controlling the transfer mechanism 31 and is configured to control the transfer position of the circuit board 1, based on a command signal from the main controller 331.

The following describes the main controller 331 and the other functional portions. The main controller 331 is a functional portion of controlling the entirety of the flux application state inspection device 12 and is configured to send and receive a variety of signals to and from the other functional portions including the illumination controller 332 and the camera controller 333.

The illumination controller 332 is a functional portion of driving and controlling the first illumination device 321a and the second illumination device 321b. The illumination controller 332 is configured to perform, for example, timing control relating to radiation of light and stop of radiation from the respective illumination devices 321a and 321b toward the circuit board 1, based on a command signal from the main controller 331. According to one or more embodiments, the illumination controller 332 controls the respective illumination devices 321a and 321b, such that the radiation of light from the first illumination device 321a toward the circuit board 1 and the radiation of light from the second illumination device 321b toward the circuit board 1 are performed at different timings.

The camera controller 333 is a functional portion of driving and controlling the camera 322. The camera controller 333 is configured to control, for example, the timing of an imaging operation of the camera 322, based on a command signal from the main controller 331. According to one or more embodiments, the camera controller 333 controls the camera 322, such as to perform imaging operations both at a timing when the light is radiated by the first illumination device 321a and at a timing when the light is radiated by the second illumination device 321b. This enables the first image and the second image to be obtained.

The image import portion 334 is a functional portion of importing the first image and the second image taken and obtained by the camera 322. The respective images imported by the image import portion 334 are stored into the image storage portion 342a.

The first specification portion 335 is configured to specify each electrode area DR that indicate an existing area of the electrode 3 in the circuit board 1 (as shown in FIG. 10), based on the first image. More specifically, the first specification portion 335 processes the first image by a binarization process, based on the threshold value stored in the inspection information storage portion 342b, so as to obtain a binarized image. In the binarized image, a location corresponding to each of the electrodes 3 is shown as a bright portion (1), irrespective of whether the flux 7 is applied to the electrode 3, whereas a location corresponding to the other part (the base material portion 6) is shown as a dark portion (0). The first specification portion 335 specifies the bright portion in the binarized image as the electrode area DR. The electrode area DR serves as an inspection area that is an object of determination of whether the flux 7 is appropriately applied. According to one or more embodiments, a process of specifying the electrode area DR by the first specification portion 335 corresponds to the “first specification process”.

The second specification portion 336 is configured to specify at least one of a flux application area FR which is located in the electrode area DR and which indicates an area with the flux 7 applied thereto (as shown in FIG. 12 and FIG. 14) and an electrode exposure area RR which is located in the electrode area DR and which indicates an area with the electrode 3 exposed thereon (as shown in FIG. 14), based on the second image. According to one or more embodiments, the second specification portion 336 specifies the flux application area FR, based on the second image.

In the process of specifying the flux application area FR, the second specification portion 336 extracts a portion having a luminance value within the numerical range stored in the inspection information storage portion 342b, in the second image, so as to extract a gray portion in the second image. The second specification portion 336 then specifies a region located in the electrode area DR, in the extracted gray portion, as the flux application area FR. According to one or more embodiments, a process of specifying the flux application area FR by the second specification portion 336 corresponds to the “second specification process”.

The determination portion 337 performs an inspection for the flux 7 applied to the circuit board 1, based on the flux application area FR specified by the second specification portion 336. More specifically, the determination portion 337 calculates an area (the number of pixels according to one or more embodiments) of the flux application area FR with regard to each electrode area DR. According to a modification, the determination portion 337 may calculate a total area of all the flux application areas FR located in the inspection target range KH.

The determination portion 337 then compares the calculated area of each flux application area FR with an area threshold value stored in advance in the inspection area storage portion 342b. When the area of at least one flux application area FR is equal to or smaller than the area threshold value, the determination portion 337 determines that application of the flux 7 to at least one electrode 3 is insufficient and thereby determines the application state of the flux 7 as “defective”. When the calculated areas of all the flux application areas FR are larger than the area threshold value, on the other hand, the determination portion 337 determines that the flux 7 is appropriately applied to all of the plurality of electrodes 3 corresponding to one electronic component 5 and thereby determines the application state of the flux 7 as “non-defective”. In the modified configuration of the determination portion 337 that calculates the total area of all the flux application areas FR located in the inspection target range KH, the determination portion 337 compares the calculated total area with an area threshold value to perform the defective/non-defective determination.

The determination portion 337 performs the above determination with regard to all the inspection target ranges KH. When the application state of the flux 7 is determined as “defective” with regard to at least one inspection target range KH, the determination portion 337 determines that the circuit board 1 as an object of inspection has “defective” application state of the flux 7. When the application state of the flux 7 is determined as “non-defective” with regard to all the inspection target ranges KH as a result of the above determination for all the inspection target ranges KH, on the other hand, the determination portion 337 determines that the circuit board 1 as an object of inspection has “non-defective” application state of the flux 7. The results of the defective/non-defective determination (inspection results data) are stored in the inspection results storage portion 342c. According to one or more embodiments, a process of causing the determination portion 337 to perform the defective/non-defective determination with regard to the application state of the flux 7 corresponds to the “determination process”.

As described above in detail, the configuration of one or more embodiments specifies the electrode 3 as a bright portion and specifies the other part as a dark portion in the first image. The configuration of one or more embodiments accordingly enables the first specification portion 335 to more accurately and more readily specify the electrode area DR, i.e., an inspection area as an object of the determination of whether the flux 7 is appropriately applied, based on the first image. This reduces the processing load in relation to setting of the inspection area and thereby improves the efficiency of the inspection. Furthermore, this configuration enables the inspection area (the electrode area DR) to be specified without using any mark as a reference provided in the circuit board 1. This more effectively prevents a decrease in the accuracy of the inspection accompanied with a position change of the reference caused by a change in the shape of the circuit board 1 (for example, a warpage, a contraction or an expansion of the circuit board 1).

The configuration of one or more embodiments, on the other hand, specifies the exposed electrode 3e as a dark portion and specifies the electrode 3 with the flux 7 applied thereto as a brighter portion than the exposed electrode 3 (for example, a gray portion) in the second image. The configuration of one or more embodiments accordingly enables the second specification portion 336 to more accurately and more readily specify the flux application area FR, based on the second image.

This configuration of accurately specifying the electrode area DR corresponding to an inspection area and the flux application area FR provides the high accuracy of inspection in the defective/non-defective determination by the determination portion 337. This configuration accordingly ensures the sufficient accuracy of inspection even in the case of an inspection with regard to the circuit board 1 provided with a plurality of electrodes 3 arrayed at extremely small pitches (for example, a circuit board with a BGA mounted thereon).

Furthermore, the configuration of one or more embodiments sets the incident angle θ1 to be not less than 0 degree and not greater than 20 degrees and makes the light regularly reflected by the electrode 3 more likely to reach the camera 322. This configuration provides a more distinct difference between the luminance value of the electrode 3 and the luminance value of the other part in the first image. This accordingly enables the electrode area DR to be more accurately specified in the first image and thereby further enhances the accuracy of inspection.

Moreover, the configuration of one or more embodiments sets the incident angle θ2 to be not less than 55 degrees and not greater than 75 degrees and makes the light regularly reflected by the electrode 3 more unlikely to reach the camera 322. This configuration provides a more distinct difference between the luminance value of the exposed electrode 3e and the luminance value of the electrode 3 with the flux 7 applied thereto, in the second image. As a result, this enables the flux application area FR to be more accurately specified in the second image and thereby further enhances the accuracy of inspection.

The present disclosure is not limited to the description of the above embodiments but may be implemented, for example, by configurations described below. The present disclosure may also be naturally implemented by applications and modifications other than those illustrated below.

(a) According to the embodiments described above, the base material portion 6 of the circuit board 1 has green color. The base material portion 6 may, however, have another color. For example, the base material portion 6 may have blue color, red color, or brown color.

(b) According to a modification, the first illumination device 321a and the second illumination device 321b may have a function of changing (adjusting) the wavelength of the visible light radiated toward the circuit board 1. In this modification, the illumination controller 332 may be configured to control the wavelengths of the respective lights radiated from the first illumination device 321a and from the second illumination device 321b.

According to another modification, the input unit 340 may be configured to input the color (information with regard to the color) of the base material portion 6 of the circuit board 1. The illumination controller 332 may be configured to control the wavelengths of the respective lights radiated from the first illumination device 321a and from the second illumination device 321b, based on the color input via the input unit 340. In this modified configuration, the illumination controller 332 may be configured to automatically control the wavelengths of the respective lights radiated from the first illumination device 321a and from the second illumination device 321b as described below.

In one example, when the color input via the input unit 340 is green color (when the color information corresponds to green color), the illumination controller 332 may be configured to set the wavelength of the light radiated from the first illumination device 321 a to be not lower than 625 nm and not higher than 635 nm or to be not lower than 445 nm and not higher than 455 nm and to set the wavelength of the light radiated from the second illumination device 321 b to be not lower than 520 nm and not higher than 635 nm. In another example, when the color input via the input unit 340 is blue color (when the color information corresponds to blue color), the illumination controller 332 may be configured to set the wavelength of the light radiated from the first illumination device 321 a to be not lower than 520 nm and not higher than 635 nm and to set the wavelength of the light radiated from the second illumination device 321 b to be not lower than 520 nm and not higher than 635 nm. In still another example, when the color input via the input unit 340 is red color or brown color (when the color information corresponds to red color or brown color), the illumination controller 332 may be configured to set the wavelength of the light radiated from the first illumination device 321a to be not lower than 445 nm and not higher than 530 nm and to set the wavelength of the light radiated from the second illumination device 321 b to be not lower than 520 nm and not higher than 635 nm.

The configuration of automatically and appropriately setting the wavelengths of the irradiation lights according to the color of the base material portion 6 as described above more certainly ensures the high accuracy of inspection and further enhances the convenience in relation to the inspection. In this modified configuration, the illumination controller 332 corresponds to the “wavelength controller”.

(c) According to the embodiments described above, the camera 322 is configured to perform the imaging operation for obtaining the first image and the imaging operation for obtaining the second image at different timings. According to a modification, the camera 322 may be configured to simultaneously take an image of the light radiated from the first illumination device 321a to the circuit board 1 and reflected from the circuit board 1 and an image of the light radiated from the second illumination device 321b to the circuit board 1 and reflected from the circuit board 1. In other words, the camera 322 may be configured to perform the imaging operation for obtaining the first image and the imaging operation for obtaining the second image at the same timing. This modified configuration enables the first image and the second image to be obtained by one imaging operation of the camera 322. This further enhances the efficiency of the inspection.

In this modified configuration of obtaining both the images by one imaging operation of the camera 322, the wavelength of the light radiated from the first illumination device 321a and the wavelength of the light radiated from the second illumination device 321 are set to be different from each other. For example, the first illumination device 321a may be set to radiate red visible light, while the second illumination device 321b may be set to radiate green visible light. The camera 322 may be configured to have sensitivities to both the lights radiated from the first illumination device 321a and from the second illumination device 321b.

(d) According to the embodiments described above, the second specification portion 336 is configured to specify the flux application area FR, based on the second image. According to a modification, the second specification portion 336 may be configured to specify an electrode exposure area RR, based on the second image. The electrode exposure area RR may be specified by, for example, performing a binariation process or the like and extracting a dark portion in the second image.

In the modified configuration of specifying the electrode exposure area RR, the determination portion 337 may be configured to perform the defective/non-defective determination with regard to the application state of the flux 7, based on, for example, the area of the specified electrode exposure area RR.

According to another modification, the second specification portion 336 may be configured to specify both the flux application area FR and the electrode exposure area RR. The determination portion 337 may be configured to perform the defective/non-defective determination with regard to the application state of the flux 7, based on both the specified areas FR and RR.

(e) According to the embodiments described above, the determination portion 337 is configured to perform an inspection for the application state of the flux 7 by comparing the calculated area of the flux application area FR with the area threshold value stored in advance in the inspection information storage portion 342b. According to a modification, the determination portion 337 may be configured to calculate a ratio of the area of the flux application area FR to the area of the electrode area DR and determine the application state of the flux 7, based on the calculated ratio. The determination portion 337 may employ any other determination technique (for example, a determination technique based on the shape of the flux application area FR and the shape of the electrode exposure area RR) to determine the application state of the flux 7.

(f) According to the embodiments described above, the first illumination device 321a is configured to radiate the visible light having the complementary color of the color of the base material portion 6. According to a modification, however, the first illumination device 321a may be configured to radiate ultraviolet light in a range of not lower than 320 nm and not higher than 400 nm. This modification does not require to set the irradiation light according to the color of the base material portion 6 of the circuit board 1 in the process of obtaining the first image. This enhances the convenience in relation to the inspection.

(g) According to the embodiments described above, the circuit board 1 is configured by a glass epoxy substrate. The circuit board 1 may, however, be configured by another type of substrate. For example, the circuit board 1 may be configured by a ceramic substrate.

(h) According to the embodiments described above, a BGA is employed as an example of the electronic component 5. The electronic component 5 may, however, be another semiconductor package (for example, CSP (Chip Size Package)).

(i) According to the embodiments described above, the flux 7 is configured to individually cover the plurality of electrodes 3 configuring one electrode group 3x. According to a modification, however, the flux 7 may be configured to collectively cover all of these electrodes 3.

Although the disclosure has been described with respect to only a limited number of embodiments, those skilled in the art, having benefit of this disclosure, will appreciate that various other embodiments may be devised without departing from the scope of the present invention. Accordingly, the scope of the invention should be limited only by the attached claims.

### Reference Signs List

1 . . . printed circuit board (circuit board), 3 . . . electrode, 6 . . . base material portion, 7 . . . flux, 12 . . . flux application state inspection device, 321a . . . first illumination device (first irradiation unit), 321b . . . second illumination device (second irradiation unit), 322 . . . camera (imaging unit), 332 . . . illumination controller (wavelength controller), 335 . . . first specification portion (first specification unit), 336 . . . second specification portion (second specification unit), 337 . . . determination portion (determination unit), 340 . . . input unit (input unit), DR . . . electrode area, FR . . . flux application area, RR . . . electrode exposure area

What is claimed is:

1. A flux application state inspection device that inspects a transparent or translucent flux applied to an electrode of a circuit board, the flux application state inspection device comprising:
a first illuminator that irradiates the circuit board with first irradiation light that is ultraviolet light or visible light at a first incident angle that is not less than 0 degree and not greater than 30 degrees, wherein
the ultraviolet light has a wavelength of not lower than 320 nm and not higher than 400 nm, and
the visible light has a complementary color of a color of a base material portion of the circuit board;
a second illuminator that irradiates the circuit board with second irradiation light that is visible light having red color or green color, at a second incident angle that is larger than the first incident angle;
an imaging device that is disposed above the circuit board such that an optical axis of the imaging device is orthogonal to the circuit board, takes a first image of light radiated from the first illuminator to the circuit board and reflected from the circuit board, and takes a second image of light radiated from the second illuminator to the circuit board and reflected from the circuit board; and
a control device that:
based on the first image, specifies an electrode area that indicates an existing area of the electrode in the circuit board,
based on the second image, specifies at least one of a flux application area and an electrode exposure area, wherein
the flux application area is located in the electrode area, and the flux is applied to the flux application area, and
the electrode exposure area is located in the electrode area, and the electrode is exposed on the electrode exposure area, and
detects whether an application state of the flux to the electrode is defective or non-defective, based on at least one of the flux application area and the electrode exposure area that have been specified.

2. The flux application state inspection device according to claim 1, wherein
a wavelength of the first irradiation light and a wavelength of the second irradiation light are set to be different from each other, and
the imaging device simultaneously takes the first image and the second image.

3. The flux application state inspection device according to claim 1, wherein
the first incident angle is set to be not less than 0 degree and not greater than 20 degrees.

4. The flux application state inspection device according to claim 1, wherein
the second incident angle is set to be not less than 55 degrees and not greater than 75 degrees.

5. The flux application state inspection device according to claim 1, wherein
the first illuminator radiates, as the first irradiation light, ultraviolet light having a wavelength of not lower than 320 nm and not higher than 400 nm.

6. The flux application state inspection device according to claim 1, wherein
the first illuminator radiates, as the first irradiation light, the visible light having the complementary color of the color of the base material portion,
the flux application state inspection device further comprising:
an input device receives an input of the color of the base material portion, wherein
the control device:
automatically controls wavelengths of the first irradiation light and the second irradiation light based on the color input via the input device,
in a case where the color input via the input device is green color, sets the wavelength of the first irradiation light to be not lower than 625 nm and not higher than 635 nm, or to be not lower than 445 nm and not higher than 455 nm, and sets the wavelength of the second irradiation light to be not lower than 520 nm and not higher than 635 nm,
in a case where the color input via the input device is blue color, sets the wavelength of the first irradiation light to be not lower than 520 nm and not higher than 635 nm, and sets the wavelength of the second irradiation light to be not lower than 520 nm and not higher than 635 nm, and
in a case where the color input via the input device is red color or brown color, sets the wavelength of the first irradiation light to be not lower than 445 nm and not higher than 530 nm, and sets the wavelength of the second irradiation light to be not lower than 520 nm and not higher than 635 nm.

7. A flux application state inspection method for inspecting a transparent or translucent flux applied to an electrode of a circuit board, the flux application state inspection method comprising:
a first irradiation process of irradiating the circuit board with first irradiation light that is ultraviolet light or visible light at a first incident angle that is not less than 0 degree and not greater than 30 degrees, wherein
the ultraviolet light has a wavelength of not lower than 320 nm and not higher than 400 nm, and
the visible light has a complementary color of a color of a base material portion of the circuit board;
a second irradiation process of irradiating the circuit board with second irradiation light that is visible light having red color or green color, at second incident angle that is a larger than the first incident angle;
a first imaging process of taking, with an imaging device disposed above the circuit board such that an optical axis of the imaging device is orthogonal to the circuit board, a first image of light radiated to the circuit board in the first irradiation process and reflected from the circuit board;
a second imaging process of taking, with the imaging device, a second image of light radiated to the circuit board in the second irradiation process and reflected from the circuit board;
a first specification process of specifying, based on the first image, an electrode area that indicates an existing area of the electrode in the circuit board;
a second specification process of specifying, based on the second image, at least one of a flux application area and an electrode exposure area, wherein
the flux application area is located in the electrode area, and the flux is applied to the flux application area, and
the electrode exposure area is located in the electrode area, and the electrode is exposed on the electrode exposure area; and
a detection process of detecting whether an application state of the flux to the electrode is defective or non-defective, based on at least one of the flux application area and the electrode exposure area that have been specified.
